(19) United States
(12) Patent Application Publication
(10) Pub. No.: US 2011/0027051 A1
(43) Pub. Date: Feb. 3, 2011

(54) DRIVING DEVICE AND VACUUM PROCESSING APPARATUS

(75) Inventors: Takuma Miyauchi, Tokyo (JP); Kouichi Yoshizuka, Tokyo (JP)

Correspondence Address: FITZPATRICK CELLA HARPER & SCINTO, 1290 Avenue of the Americas, NEW YORK, NY, 10104-3800, US

(73) Assignee: CANON ANELVA CORPORATION, Kawasaki-shi (JP)

(21) Appl. No.: 12/838,053

(22) Filed: Jul. 16, 2010

(30) Foreign Application Priority Data
Jul. 28, 2009 (JP) 2009-175094

(51) Int. Cl. H01L 21/677; H02K 7/06

(52) U.S. Cl. 414/217; 310/83

(57) ABSTRACT

A magnetic screw driving device 9 is for rotating a helical magnet shaft 11, that is axially supported on a housing 17, through a drive shaft 13 connected to a motor. The drive shaft 13 and the helical magnet shaft 11 are respectively provided with cylindrical collars 19 through which the drive shaft 13 and the helical magnet shaft 11 are inserted and which are mounted airtightly and oil seals 20 mounted to the housing 17 to come in sliding contact with surfaces of the collars 19 to thereby seal a lubricant Gr in the housing 17. As a result, it is possible to provide a magnetic screw driving device which contributes to reduction in maintenance cost and running cost.

### FIELD OF THE INVENTION

The present invention relates to a driving device and a vacuum processing apparatus including the driving device and particularly to a driving device having an oil seal structure and a rotating shaft and a vacuum processing apparatus including the driving device.

### BACKGROUND OF THE INVENTION

In a semiconductor manufacturing process such as a film forming step, adhesion of dust to a film formation face need be prevented and therefore reduction of dust existing in a vacuum vessel is required. The dust is generated in the vacuum vessel due to various causes and known causes are peeling off of a film of film forming material stuck on a substrate holder and wear due to contact between a substrate and other members, for example. In particular, a vacuum processing apparatus having a substrate transfer device includes a structure in which members forming the transfer device come in contact with each other and therefore there is a need for a transfer device that can further suppress generation of dust due to wear and cutting erosion.

To suppress generation of dust, it is preferable to use a noncontact transmission transfer device. As the noncontact transmission transfer device, various methods have been proposed conventionally. Among them, there is a known method utilizing magnetic coupling (hereinafter referred to as a “magnetic transfer device”) as a method having a relatively simple structure. As the magnetic transfer device, a linear transfer device formed by combining helical magnetic screws and magnetic poles has been proposed as disclosed in the U.S. Pat. No. 5,377,816, Japanese Patent Application Laid-Open No. 10-159934, Japanese Patent Application Laid-Open No. 2001-206548, Japanese Patent Application Laid-Open No. 2008-297092, and Japanese Patent Application Laid-Open No. 8-274142, for example.

As an example of prior art, a technique disclosed in Japanese Patent Application Laid-Open No. 10-159934 will be described. The technique disclosed in Japanese Patent Application Laid-Open No. 10-159934 is a magnetic transfer device used for an in-line vacuum processing apparatus in which a plurality of processing chambers are connected in series. A load lock chamber, a processing chamber, and an unload lock chamber are connected with gate valves interposed therebetween and a magnetic transfer device is disposed to pass through the respective chambers. A substrate held on a carrier can be moved between the chambers by the magnetic transfer device.

A magnetic screw driving device is used for the magnetic transfer device. A carrier-side magnet is provided to a lower end portion of each carrier and magnetic screws are disposed on chamber sides below the carrier-side magnet. Helical magnetic poles formed on each magnetic screw are magnetically coupled to the carrier-side magnet and therefore it is possible to transfer the carrier in a horizontal direction as the magnetic screws rotate. Because the respective chambers are separated by the gate valves, the magnetic screw driving device is provided to each chamber.

During normal operation, the magnetic screw driving device is housed in a case and is isolated from a film forming area in the vacuum vessel. However, the area including the magnetic screw driving device where the magnetic screws and the like are disposed and the film forming area may be connected during maintenance and therefore it is necessary to minimize dust in the magnetic screw driving device.

The magnetic screw driving device used in Japanese Patent Application Laid-Open No. 10-159934 will be described. The magnetic screw driving device is a device for transmitting torque from a motor (not shown) to the magnetic screw and includes a power transmitting portion having a pair of bevel gears as a main component. By using the magnetic screw driving device, it is possible to drive a carrier without contact. As a result, the carrier comes in contact with only a self-weight receiving bearing and a guide bearing while it is moving and it is possible to substantially suppress generation of the dust. However, in this magnetic screw driving device, wear of gears in the power transmitting portion is unavoidable and may make unstable of transfer of the carrier or phase shift of the magnetic poles. Therefore, a lubricant is applied to sliding portions of the gears in the power transmitting portion to thereby suppress the wear and an oil seal is used to seal the lubricant in the power transmitting portion to thereby prevent spattering of the lubricant.

### BRIEF SUMMARY OF THE INVENTION

However, with the structure for sealing the lubricant in the power transmitting portion by using the oil seal 105 in sliding contact with a rotating shaft 106 or 107 as shown in FIG. 6, it is impossible to avoid wear of a sliding contact portion A between the rotating shaft 106 or 107 and the oil seal 105. To avoid negative impact of the wear, periodic maintenance for replacing the oil seal 105 and the rotating shafts 106 and 107 is necessary. However, the rotating shafts 106 and 107 are extending through the whole magnetic transfer device, which complicates the maintenance work. Moreover, the rotating shafts are expensive, which increases cost of the maintenance.

The present invention has been made with the above problems in view and it is an object of the invention to provide a driving device in which maintenance work of power transmitting portions including sealed-in lubricant is simplified to thereby contribute to reduction in the maintenance cost and running cost and a vacuum processing apparatus including the driving device.

A driving device according to the present invention is a driving device used for transfer of a substrate in a vacuum processing apparatus, the device including:

a housing;

at least one rotating shaft disposed to pass through a wall portion of the housing;

a cylindrical collar mounted to the rotating shaft in a state in which the rotating shaft is inserted through the collar; and

a seal member which comes in sliding contact with a surface of the collar in order to maintain airtightness between the collar and the housing and which is mounted on the housing side.

The rotating shaft is inserted through the collar so that airtightness is maintained between the rotating shaft and the collar.

A vacuum processing apparatus according to the invention is a vacuum processing apparatus including a processing chamber for carrying out vacuum processing of a substrate and a transfer device for transferring the substrate into the processing chamber.

The transfer device includes the driving device according to the invention.

By employing the invention, it is possible to reduce cost required for maintenance work of the driving device or the vacuum processing apparatus. In other words, the rotating shaft need not be replaced and only the collar need be replaced and therefore it is possible to reduce replacement parts. Because only the collar need be replaced, it is unnecessary to disassemble the whole driving device, which shortens the time required for the maintenance. Moreover, the reduction in the cost of the maintenance contributes to reduction in running cost of the transfer device or the vacuum processing apparatus.

### BRIEF DESCRIPTION OF THE SEVERAL VIEWS OF THE DRAWINGS

FIG. 1 is a schematic sectional view of an in-line vacuum processing apparatus according to an embodiment of the invention;

FIG. 2 is a schematic diagram of a magnetic transfer device according to the embodiment of the invention;

FIG. 3 is a sectional view taken along a line A-A of the magnetic transfer device according to the embodiment of the invention;

FIG. 4 is a sectional view of a magnetic screw driving device according to the embodiment of the invention;

FIG. 5 is a partial exploded view of the magnetic screw driving device according to the embodiment of the invention; and

FIG. 6 is a schematic diagram showing wear of a sliding contact face between a rotating shaft and an oil seal in a prior-art driving device.

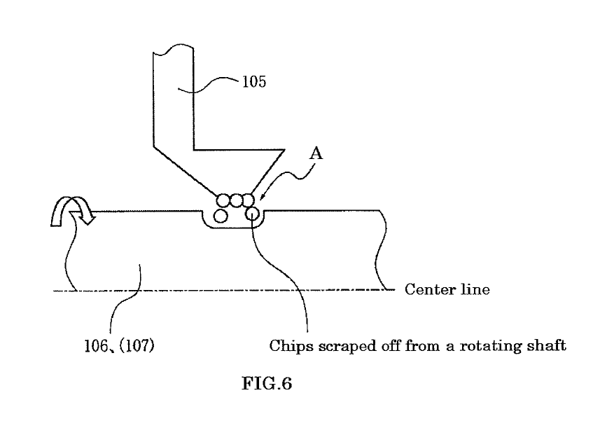

### DETAILED DESCRIPTION OF THE INVENTION

An embodiment of the present invention will be described below with reference to the drawings. Members, arrangement, and the like which will be described below are examples for embodying the invention, but are not intended to limit the invention. It is a matter of course that they can be changed in various ways along the gist of the invention.

The driving device of the invention is used as a component member of a transfer device for transferring substrates in a vacuum processing apparatus. The driving device of the invention includes a housing, at least one rotating shaft disposed to pass through wall portions of the housing, a cylindrical collar mounted on the rotating shaft, and a seal member mounted on the housing. The seal member is in sliding contact with a surface of the collar to maintain airtightness between the collar and the housing and the rotating shaft is inserted in such a manner as to maintain airtightness between the collar and itself.

As the driving device of the invention, there are a first form and a second form described below.

In the first form, the rotating shaft is a magnet shaft having a magnet on its surface, disposed to pass through two opposed wall portions of the housing, and rotated by a motor. The second form includes a first rotating shaft and a second rotating shaft and a collar mounted at least on the second rotating shaft. The first rotating shaft according to the invention is rotatably mounted to pass through the first wall portion of the housing and the second rotating shaft is disposed to pass through the second wall portion of the housing and the third wall portion opposed to the second wall portion. In other words, the second rotating shaft is disposed to pass through the whole housing. The second rotating shaft rotates following the first rotating shaft.

The driving device in the second form of the invention is preferably used for the magnetic-coupling magnetic transfer device described above. In other words, it is a magnetic screw driving device in which the first rotating shaft is a drive shaft and the second rotating shaft is a magnet shaft having a magnet portion on its surface. The invention will be specifically described below by taking an example in which the second form is applied to the magnetic screw driving device.

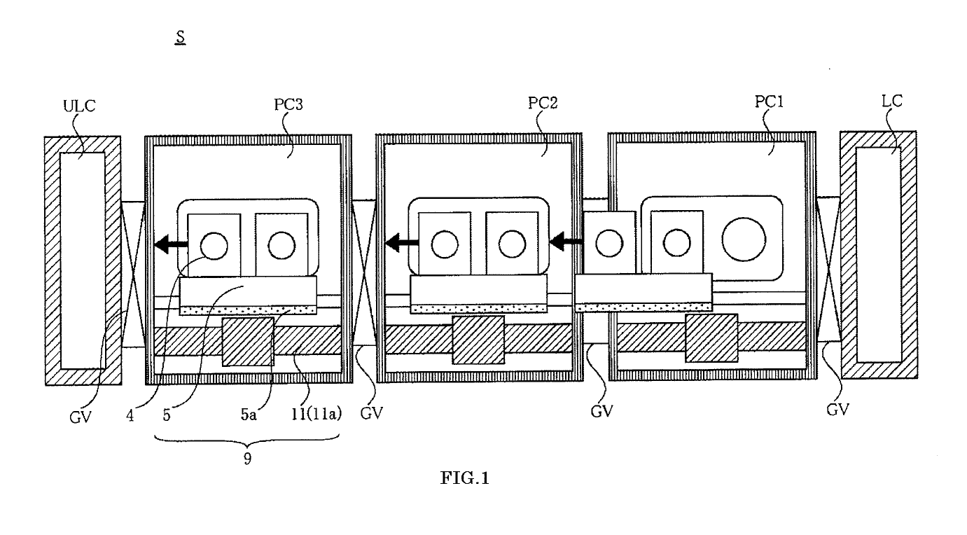

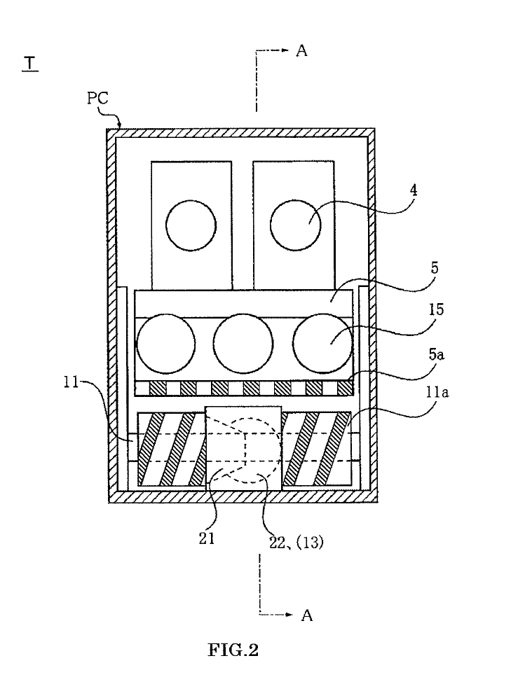

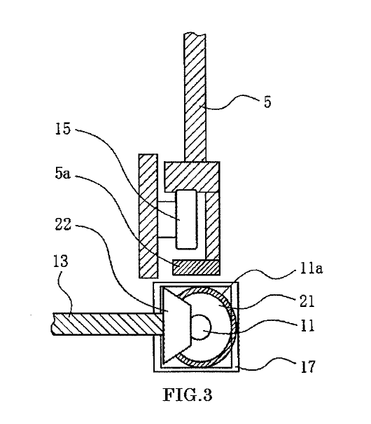

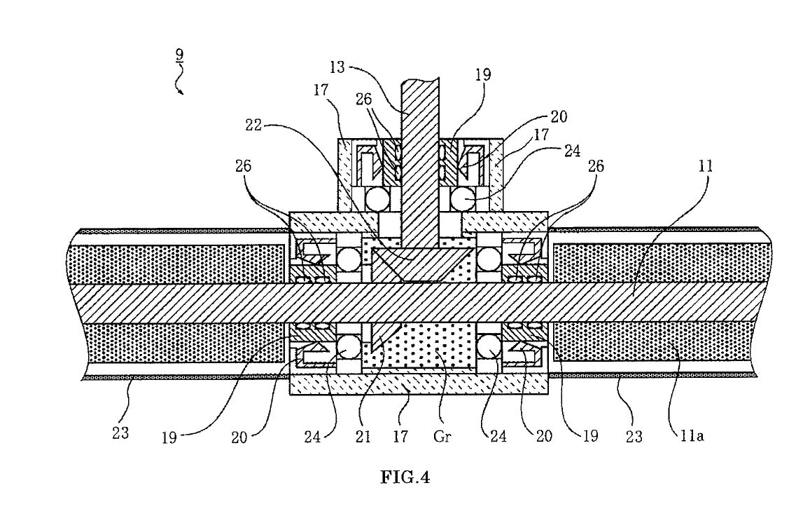

FIGS. 1 to 4 are drawings related to an in-line vacuum processing apparatus according to an exemplary embodiment of the invention. FIG. 1 is a schematic sectional view of the in-line vacuum processing apparatus, FIG. 2 is a schematic diagram of the magnetic transfer device, FIG. 3 is a sectional view taken along a line A-A in FIG. 2, and FIG. 4 is a sectional view of the magnetic screw driving device. In the embodiment, the magnetic transfer device provided to the in-line vacuum processing apparatus will be described as an example of the vacuum processing apparatus having the magnetic transfer device. To avoid complication, the drawings except part of them are simplified.

The in-line vacuum processing apparatus S (hereinafter referred to as the vacuum processing apparatus S) shown in FIG. 1 is a film forming apparatus which performs film forming processing of a hard disk substrate in vacuum and in which a load lock chamber LC, processing chambers PC (PC1, PC2, PC3), and an unload lock chamber ULC are connected with gate valves GV interposed therebetween. By opening the respective gate valves GV, internal spaces of the chambers (PC1, PC2, PC3) can be connected to each other. The respective chambers (LC, PC, ULC) are provided with magnetic transfer devices T (hereinafter referred to as the transfer device T) that can transfer a substrate 4 between the adjacent chambers.

As shown in FIGS. 1 to 3, the transfer device T includes a carrier 5 that can hold the substrate 4 and move and a magnetic screw driving device 9 (driving device) provided to each of the chambers (LC, PC, ULC) as a component. The magnetic screw driving device 9 is mainly made up of a helical magnetic shaft (second rotating shaft) 11, a drive shaft (first rotating shaft) 13 for transmitting torque to the helical magnetic shaft 11, and a motor (not shown) as a power source for supplying power to the drive shaft 13.

A carrier-side magnet portion 5a is provided to a lower end portion of each of the carriers 5. A helical magnet shaft 11 is disposed in the magnetic screw driving device 9 positioned below the carrier-side magnet portion 5a. The carrier 5 according to the embodiment is provided with a self-weight receiving bearing 15 and a guide bearing (not shown) for guiding in a transferring direction.

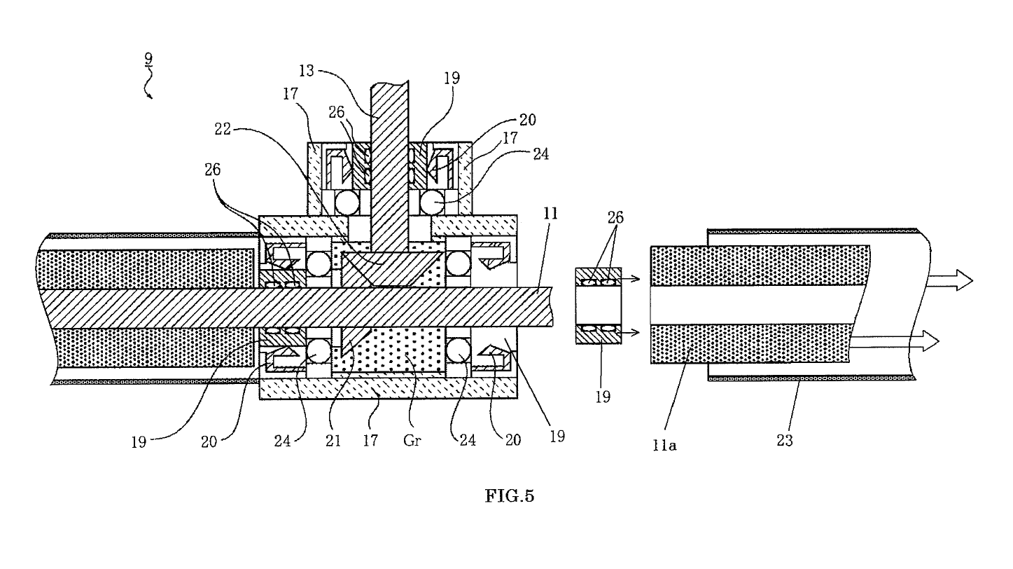

Here, the magnetic screw driving device 9 will be described based on FIGS. 4 and 5. The magnetic screw driving device 9 includes the helical magnet shaft (magnet shaft) 11, the drive shaft 13, and the motor (not shown) and transfers the torque of the motor to the helical magnet shaft 11 through the drive shaft 13 as described above. The helical magnet shaft 11 and the drive shaft 13 are disposed so that their axial directions are orthogonal to each other and a power transmitting portion for transmitting the torque is formed of a pair of bevel gears 21 and 22 at a connection between them.

A magnet portion 11a having a surface magnetized in a helical shape is formed on the helical magnet shaft 11 and magnetic poles of the carrier-side magnet portion 5a provided to the carrier 5 are formed with the same pitch as the magnet portion 11a of the helical magnet shaft 11. Therefore, it is possible to obtain magnetic coupling between the carrier-side magnet portion 5a and the magnet portion 11a of the helical magnet shaft 11 while maintaining a predetermined distance between them.

Because the magnet portion 11a of the helical magnet shaft 11 is in the helical shape, it is possible to gradually change a position of magnetic coupling with the carrier-side magnet portion 5a as the helical magnet shaft 11 rotates. Therefore, it is possible to transfer the carrier-side magnet portion 5a, i.e., the carrier 5 in the axial direction of the helical magnet shaft 11 in synchronization with rotation of the helical magnet shaft 11. The magnet portion 11a of the helical magnet shaft 11 is divided into two and the bevel gear 21 is secured to a portion between the parts of the divided magnet portion 11a. An outer periphery side of the magnet portion 11a is isolated from a vacuum side by cylindrical cases 23. End portions of the cases 23 are airtightly connected to a housing 17. However, the cases 23 are not indispensable and vacuum isolation of the inside and outside of the housing 17 from each other can be achieved by oil seals 20 described later.

The power transmitting portion is mainly made up of the helical magnet shaft 11 and the drive shaft 13 to which the bevel gears 21 and 22 are secured and the housing 17 for supporting them in predetermined positions. The helical magnet shaft 11 and the drive shaft 13 are disposed orthogonally and rotatably supported on the housing 17 through bearings 24. The helical magnet shaft 11 and the drive shaft 13 are mounted with collars 19, 19, 19 on the outer sides of their axially supported portions with respect to the housing 17.

The collars 19, 19, 19 are cylindrical stainless members and mounted after the helical magnet shaft 11 and the drive shaft 13 are inserted through them. The housing 17 is mounted with oil seals 20 as seal members for coming in sliding contact with outer periphery sides of the respective collars 19. Inside the respective collars 19, on the other hand, O-rings 26 for closing clearances between inner face sides of the collars 19 and the helical magnet shaft 11 or clearances between an inner face side of the collar 19 and the drive shaft 13 are mounted. With the oil seals 20 and the O-rings 26, a lubricant Gr such as grease filled in the housing 17 in which the bevel gears 21 and 22 are disposed can be sealed in the housing 17.

The number of O-rings 26 disposed in each of the clearances around the helical magnet shaft 11 and the drive shaft 13 may be one, but is preferably two. Frictional forces of contact of the O-rings 26 with the helical magnet shaft 11 and the drive shaft 13 are greater than frictional forces of contact of the oil seals 20 with the collars 19. In other words, the frictional force(s) generated between the collar(s) 19 and the helical magnet shaft 11 or the drive shaft 13 mounted with the collar(s) 19 in rotating directions is (are) greater than the frictional forces generated between the oil seals 20 and the collars 19 in the rotating directions. Therefore, the collars 19 rotate with the helical magnet shaft 11 and the drive shaft 13. Because the helical magnet shaft 11 and the drive shaft 13 do not come in sliding contact with the oil seals 20, it is possible to prevent them from wearing. On the other hand, surfaces of the collars 19 come in sliding contact with the oil seals 20 and the sliding contact portions of the collars 19 wear.

It is essential only that the O-rings 26 be capable of sealing in the lubricant Gr and generating greater frictional forces as described above. Therefore, a sectional shape of the O-ring 26 may be a circle, a rectangle, or a triangle and a cylindrical rubber sheet may be used as the O-ring 26. It is a matter of course that three or more O-rings 26 can be used for each collar.

The surface of the collar 19 on which the oil seal 20 slides is subjected to surface treatment for suppression of wear and improvement of adhesion to the oil seal 20 during sliding. Although the surface is given hard chrome plating and a plating surface is polished as the surface treatment in the embodiment, it can be subjected to other surface treatments using DLC, TiN and the like.

By employing the structure described above, it is possible to reduce cost required for maintenance work of the transfer device T or the vacuum processing apparatus S. In other words, the helical magnet shaft 11 and the drive shaft 13 need not be replaced and only the collars 19 need be replaced and therefore it is possible to reduce replacement parts. To put it concretely, as shown in FIG. 5, the case 23 is detached from the housing 17, the magnet portion 11a is detached from the helical magnet shaft 11 by pulling it in the axial direction, the collar 19 is similarly detached from the helical magnet shaft 11, and the collar 19 is replaced. It is preferable to simultaneously replace the O-rings 26 mounted on the collar 19.

Because only the collar 19 need be replaced, it is unnecessary to disassemble the whole magnetic screw driving device 9, which shortens the time required for the maintenance. Moreover, the reduction in the cost of the maintenance contributes to reduction in running cost of the transfer device T or the vacuum processing apparatus S.

Furthermore, the driving device according to the invention is not limited to the magnetic screw driving device. In other words, it is needless to say that other rotating shafts may be used in place of the helical magnet shaft (magnet shaft).

Moreover, the magnet shaft is driven when a direct-drive mechanism is used to directly drive the helical magnet shaft 11 (rotating shaft) for rotation and therefore the drive shaft 13 and the helical magnet shaft 11 are integrated with each other. This structure corresponds to the first form of the invention. In this case, a stator is provided to the housing 17. If the collars 19 are mounted on the helical magnet shaft 11 which is driven for rotation, it is possible to obtain similar effects to those of the invention.

1. A driving device used for transfer of a substrate in a vacuum processing apparatus, the driving device comprising:
a housing;
at least one rotating shaft disposed to pass through a wall portion of the housing;
a cylindrical collar mounted to the rotating shaft in a state in which the rotating shaft is inserted through the collar; and
a seal member which comes in sliding contact with a surface of the collar in order to maintain airtightness between the collar and the housing and which is mounted on the housing side,
wherein the rotating shaft is inserted through the collar so that airtightness is maintained between the rotating shaft and the collar.

2. A driving device according to claim 1, wherein the rotating shaft is a magnet shaft having a magnet portion on its surface, disposed to pass through two opposed wall portions of the housing, and rotated by a motor.

3. A driving device according to claim 1,
wherein the rotating shaft includes
a first rotating shaft disposed to pass through a first wall portion of the housing and supported rotatably and
a second rotating shaft disposed to pass through a second wall portion of the housing and a third wall portion opposed to the second wall portion to rotate following the first rotating shaft and
the collar is mounted to at least the second rotating shaft.

4. A driving device according to claim 3,
wherein the first rotating shaft is a drive shaft rotated by a motor,
the second rotating shaft is a magnet shaft having a magnet portion on its surface, and
the collar is mounted to each of the drive shaft and the magnet shaft.

5. A driving device according to claim 1,
wherein a frictional force generated between the collar and the rotating shaft mounted with the collar in a rotating direction is greater than a frictional force generated between the seal member and the collar in the rotating direction.

6. A vacuum processing apparatus comprising a processing chamber for carrying out vacuum processing of a substrate and a transfer device for transferring the substrate into the processing chamber,
wherein the transfer device includes the driving device according to claim 1.
